(19) United States
(12) Patent Application Publication
(10) Pub. No.: US 2011/0294243 A1
(43) Pub. Date: Dec. 1, 2011

(54) PHOTORESIST COMPOSITION AND METHOD OF FORMING PHOTORESIST PATTERN USING THE SAME

(76) Inventors: Woo-Seok Jeon, Seoul (KR); Jeong-Min Park, Seoul (KR); Byung-Uk Kim, Hwaseong-si (KR); Hyoc-Min Youn, Hwaseong-si (KR); Ki-Hyuk Koo, Hwaseong-si (KR); Su-Youn Choi, Hwaseong-si (KR); Jin-Sun Kim, Hwaseong-si (KR)

(21) Appl. No.: 13/092,629

(22) Filed: Apr. 22, 2011

(30) Foreign Application Priority Data
May 26, 2010 (KR) 10-2010-0049211

(51) Int. Cl. H01L 33/08; G03F 7/20; G03F 7/004

(52) U.S. Cl. 438/29; 430/270.1; 430/325; 257/E33.062

(57) ABSTRACT

A photoresist composition suitable for forming a high-resolution pattern, and a method of forming a photoresist pattern using the same. The photoresist composition includes about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent.

### CROSS-REFERENCE TO RELATED APPLICATION

This application claims priority from Korean Patent Application No. 10-2010-0049211 filed on May 26, 2010 in the Korean Intellectual Property Office, the disclosure of which is hereby incorporated by reference herein in its entirety.

### BACKGROUND OF THE INVENTION

1. Technical Field

The present disclosure relates to a photoresist composition and to a method of forming a photoresist pattern using the same, and more particularly, to a photoresist composition suitable for forming a high-resolution pattern, and to a method of funning a photoresist pattern using the same.

2. Description of the Related Art

Liquid crystal displays (LCDs) are one of the most widely used flat panel displays (“FPDs”). A conventional LCD includes a liquid crystal panel assembly, which has two panels having a plurality of electrodes formed thereon and a liquid crystal layer interposed between the two panels, and adjusts the amount of light transmitted through the liquid crystal layer by applying voltages to the electrodes so that liquid crystal molecules in the liquid crystal layer can be rearranged.

In general, an LCD apparatus includes a liquid crystal panel and a light source providing the liquid crystal panel with light. The liquid crystal panel includes a plurality of pixels and a plurality of thin film transistors (TFTs). The pixels and TFTs may be formed using a photolithography process that employs a photoresist composition.

The photoresist composition may includes a positive photoresist composition or a negative photoresist composition. In general, using a negative photoresist composition for forming fine patterns is generally more suitable for achieving a high resolution than using a positive photoresist composition.

In the case of using the negative photoresist composition, however, a photoresist film may be dissolved faster at its lower portion than at its upper portion. Thus, the resultant photoresist pattern may have a reverse-tapered shape or a defective profile such as an undercut during developing. In such a case, it may not be possible to observe a critical dimension (CD) of a lower pattern during an inspection process preceded by the developing, and the uniformity in the CD may be lowered. Consequently, using the negative photoresist composition may not suitable for forming a high-resolution pattern.

Thus, there is a need in the art for a photoresist composition suitable for forming a high-resolution pattern and for a method of forming a photoresist pattern using a photoresist composition suitable for forming a high-resolution pattern.

### SUMMARY OF THE INVENTION

The present invention provides a photoresist composition suitable for forming a high-resolution pattern.

The present invention may provide a method of forming a photoresist pattern using a photoresist composition suitable for forming a high-resolution pattern. According to an aspect of the present invention, there is provided a photoresist composition including about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent.

According to another aspect of the present invention, there is provided a method of forming a photoresist pattern including forming a photoresist film by coating a photoresist composition comprising about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent, exposing the photoresist film to light and partially removing the photoresist film to form a photoresist pattern.

According to another aspect of the present invention, a method for manufacturing a display device is provided. The method includes forming a gate line and a gate electrode on a first substrate, forming a gate insulating layer on the first substrate and the gate electrode, forming a semiconductor layer on the gate insulating layer, forming a data line, a source electrode, and a drain electrode on the gate insulating layer and the semiconductor layer, forming a color filter in a pixel area on the drain electrode and the gate insulating layer, forming a black matrix made of opaque material overlapping an upper portion of a thin film transistor (TFT) having the gate electrode, the source electrode and the drain electrode as three terminals, forming a passivation layer on the color filter and the black matrix, forming a conductive film for forming a pixel electrode on the passivation layer. The method further includes forming a photoresist film by coating a photoresist composition comprising about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent, exposing the photoresist film to light, partially removing a portion of the photoresist film which is not exposed to light using a development solution to thereby form a photoresist pattern, etching the conductive film for forming the pixel electrode using the formed photoresist pattern as an etch mask, thereby forming the pixel electrode and forming a second substrate including a common electrode on the pixel area of the first substrate.

### BRIEF DESCRIPTION OF THE DRAWINGS

Exemplary embodiments of the present invention can be understood in more detail from the following description taken in conjunction with the attached drawings in which:

FIGS. 1 through 3 are views illustrating process steps in a method of forming a photoresist pattern according to an exemplary embodiment of the present invention;

FIG. 4 is a layout view illustrating a display device manufactured by a manufacturing method according to an exemplary embodiment of the present invention;

FIG. 5 is a cross-sectional view of the display device of FIG. 4, taken along line A-A; and

FIGS. 6 through 15 are cross-sectional views illustrating a method for manufacturing the display device shown in FIG. 4.

### DETAILED DESCRIPTION OF EXEMPLARY EMBODIMENTS OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. In the drawings, the thicknesses of layers and regions are exaggerated for clarity.

As used herein, the singular forms “a,” “an” and “the” are intended to include the plural forms as well, unless the context clearly indicates otherwise. It will be further understood that the terms “comprises” and/or “made of” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

A photoresist composition according to an exemplary embodiment of the present invention will now be described in detail.

Photoresist Composition

A photoresist composition according to an exemplary embodiment of the present invention includes about 10 to about 45 parts by weight of an alkali soluble binder resin including a hydroxyl group; about 0.1 to about 5 parts by weight of a photo-acid generator; about 1 to about 5 parts by weight of a cross-linker that cross-links the alkali-soluble binder resin including the hydroxyl group; about 0.3 to about 3 parts by weight of a quinone diazide compound; and a remainder of a solvent.

The alkali-soluble binder resin including a hydroxyl group is dissolved in an alkaline solution such as, for example, an aqueous alkaline developer but is not dissolved in water. In addition, the alkali-soluble binder resin including a hydroxyl group may form a cross-linking reaction in the presence of a cross-linker. Once it is cross-linked, it may become insoluble in an alkaline medium.

The alkali-soluble binder resin may be, for example, a novolac resin. The novolac resin may be prepared by allowing a phenol compound to react with an aldehyde compound or a ketone compound in the presence of an acidic catalyst.

Examples of the phenol compound used for preparation of the novolac resin may include, but are not limited to phenol, o-cresol, m-cresol, p-cresol, 2,3-dimethyl phenol, 3,4-dimethyl phenol, 3,5-dimethyl phenol, 2,4-dimethyl phenol, 2,6-dimethyl phenol, 2,3,6-trimethyl phenol, 2-t-butyl phenol, 3-t-butyl phenol, 4-t-butyl phenol, 2-methyl resorcinol, 4-methyl resorcinol, 5-methyl resorcinol, 2-methyl resorcinol, 4-t-butyl catechol, 2-methoxy phenol, 3-methoxy phenol, 2-propyl phenol, 3-propyl phenol, 4-propyl phenol, 2-isopropyl phenol, 2-methoxy-5-methyl phenol, 2-t-butyl-5-methyl phenol, thymol, isothymol, etc. These can be used alone or in a combination thereof.

Examples of the aldehyde compound used for preparation of the novolac resin may include but are not limited to formaldehyde, formalin, p-formaldehyde, trioxane, acetaldehyde, propylaldehyde, benzaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, terephthalic acid aldehyde, etc. These can be used alone or in a combination thereof.

Examples of the ketone compound used for preparation of the novolac resin may include but are not limited to acetone, methylethylketone, diethyl ketone, diphenyl ketone, etc. These can be used alone or in a combination thereof.

The novolac resin obtained by condensation of m-cresol and p-cresol mixed in a ratio of about 30:70 to about 70:30 by weight with a catalyst, may be beneficially used in view of sensitivity controllability of a negative photoresist.

The novolac resin preferably has a polystyrene-reduced weight-average molecular weight in a range of about 1,000 to about 10,000, more preferably in a range of about 3,000 to about 7,000, as measured by gel permeation chromatography (GPC). When the average molecular weight of the novolac resin is excessively small, a photoresist pattern formed from the photoresist composition may be damaged by an alkali developing solution due to a trivial effect of a molecular weight increase even if a cross-linking reaction occurs at an exposed portion. When the average molecular weight of the novolac resin is excessively high, the photoresist pattern may not be clear since a solubility difference between the exposed portion and an unexposed portion may be small.

The content of the alkali-soluble binder resin including a hydroxyl group may be in a range of about 10 to about 45 parts by weight based on 100 parts by weight of the photoresist composition. When the content of the alkali-soluble binder resin is less than 10 parts by weight, the viscosity of the photoresist composition may be too low, and thus it may be difficult to form a photoresist film having a desired thickness. However, when the content of the alkali-soluble binder resin is greater than 45 parts by weight, the viscosity of the photoresist composition may be excessively high, and thus it may also be difficult to form a photoresist film having a uniform thickness.

The photo-acid generator can be illuminated with light to generate an acid, such as a Bronsted acid or Lewis acid. Examples of the photo-acid generator may include but are not limited to an onium salt, a halogenated organic compound, a α,α′-bis(sulfonyl)diazomethane compound, a sulfone compound, an organic acid-ester compound, an organic acid-amide compound, an organic acid-imide compound, or the like. These can be used alone or in a combination thereof. Specifically, examples of the photo-acid generator may include but are not limited to an aromatic sulfonic acid ester, an aromatic iodonium salt, an aromatic sulfonium salt, an aromatic compound containing a halogenated alkyl remainder, or the like.

Examples of the onium compound may include but are not limited to a diazonium salt, an ammonium salt, an iodonium salt such as diphenyliodonium triflate, a sulfonium salt such as triphenylsulfonium triflate, a phosphonium salt, an arsonium salt, an oxonium salt, or the like.

Examples of the halogenated organic compound can include but are not limited to a halogen-containing oxadiazole compound, a halogen-containing triazine compound, a halogen-containing triazine compound, a halogen-containing acetophenone compound, a halogen-containing benzophenone compound, a halogen-containing sulfoxide compound, a halogen-containing sulfonic compound, a halogen-containing thiazole compound, a halogen-containing oxazole compound, a halogen-containing triazole compound, a halogen-containing 2-pyrone compound, a halogen-containing heterocyclic compound, a halogen-containing aliphatic hydrocarbon, a halogen-containing aromatic hydrocarbon, a sulfonyl halide compound, or the like.

Specifically, examples of the halogenated organic compound may include but are not limited to tris(2,3-dibromopropyl)phosphate, tris(2,3-dibromo-3-chloropropyl)phosphate, tetrabromochlorobutane, 2-[2-(3,4-dimethoxyphenyl)ethenyl]-4,6-bis(trichloromethyl)-S-triazine, hexachlorobenzene, hexabromobenzene, hexabromocyclododecane, hexabromocyclododecene, hexabromobiphenyl, allyltribromophenylether, tetrachlorobisphenol A, tetrabromobisphenol A, bis(chloroethyl)ether of tetrachlorobisphenol A, tetrachlorobisphenol S, tetrabromobisphenol S, bis(2,3-dichloropropyl)ether of tetrachlorobisphenol A, bis(2,3-dibromopropyl)ether of tetrabromobisphenol A, bis(chloroethyl)ether of tetrachlorobisphenol S, bis(bromoethyl)ether of tetrabromobisphenol S, bis(2,3-dichloropropyl)ether of bisphenol S, bis(2,3-dibromopropyl)ether of bisphenol S, tris(2,3-dibromopropyl)isocyanurate, 2,2-bis(4-hydroxy-3,5-dibromophenyl)propane, 2,2-bis(4-(2-hydroxyethoxy)-3,5-dibromophenyl)propane, dichlorodiphenyltrichloroethane, pentachlorophenol, 2,4,6-trichlorophenyl-4-nitrophenylether, 4,5,6,7-tetrachlorophthalide, 1,1-bis(4-chlorophenyl)ethanol, 1,1-bis(4-chlorophenyl)-2,2,2-trichloroethanol, 2,4,4′,5-tetrachlorodiphenylsulfide, 2,4,4′,5-tetrachlorodiphenylsulfone, or the like.

Examples of the α,α′-bis(sulfonyl)diazomethane compound can include but are not limited to α,α′-bis(sulfonyl)diazomethane containing an alkyl group, an alkenyl group, an aralkyl group, an aromatic group or a heterocyclic group, which can be symmetrically substituted, non-symmetrically substituted, or not substituted, or the like.

Examples of the sulfone compound can include but are not limited to a sulfone compound and a disulfone compound, which comprises an alkyl group, an alkenyl group, an aralkyl group, an aromatic group or a heterocyclic group, which can be symmetrically substituted, non-symmetrically substituted, or not substituted, or the like.

Examples of the organic acid ester may include but are not limited to carboxylic acid ester, sulfonic acid ester, or phosphoric acid ester, and the like. Examples of the organic acid amide may include but are not limited to carboxylic acid amide, sulfonic acid amide, phosphoric acid amide, or the like. Examples of the organic acid imide may include but are not limited to carboxylic acid imide, sulfonic acid imide, phosphoric acid imide, or the like.

Moreover, examples of the photo-acid generator can further include but are not limited to cyclohexylmethyl(2-oxocyclohexyl)sulfonium trifluoromethane sulfonate, dicyclohexylmethyl(2-oxocyclohexyl)sulfonium trifluoromethane sulfonate, 2-oxocyclohexyl(2-norbornyl)sulfonium trifluoromethane sulfonate, 2-cyclohexylsulfonylcyclohexanone, dimethyl(2-oxocyclohexyl)sulfonium trifluoromethane sulfonate, triphenylsulfonium trifluoromethane sulfonate, diphenyliodonium trifluoromethane sulfonate, N-hydroxysuccinimidyl trifluoromethane sulfonate, phenyl p-toluene sulfonate, or the like. These can be used alone or in a combination thereof.

The content of the photo-acid generator may be in a range of about 0.1 to about 5 parts by weight based on 100 parts by weight of the photoresist composition. If the content of the photo-acid generator is less than 0.1 parts by weight or greater than 5 parts by weight, a photoresist pattern formed from the photoresist composition may have undesirably poor resolution or adversely affect sensitivity.

The cross-linker may cross-link the alkali-soluble binder resin including a hydroxyl group in the presence of acid. The cross-linker makes the alkali-soluble binder resin including a hydroxyl group be insoluble at its exposed portion by an alkali developing solution, and may be activated by the acid generated by the exposure, thereby cross-linking the alkali-soluble binder resin including a hydroxyl group.

Examples of the cross-linker may include but are not limited to urea-formaldehyde, melamine-formaldehyde, benzoguanamine-formaldehyde, glycoluril-formaldehyde, hexa(methoxymethyl)melamine, or a combination of two or more of the foregoing compounds. Among the above, hexa(methoxymethyl)melamine may be preferable.

The content of the cross-linker may be in a range of about 1 to about 5 parts by weight based on the total weight of the photoresist composition. When the content of the cross-linker is less than about 1 part by weight, the cross-linking reaction may not be sufficiently performed, so that the residual film ratio of the photoresist pattern developed by the alkali developing solution may be considerably reduced or the photoresist pattern may be liable to deformation such as swelling or meandering. When the content of the cross-linker is greater than about 5 parts by weight, the resolution may be easily lowered and stripping resistance with respect to an insulating substrate may increase, thereby adversely affecting the etching process.

The quinone diazide compound may improve an inner angle of the photoresist pattern and suppress reverse-taper and undercut phenomena of a pattern profile.

Examples of the quinone diazide compound may include but are not limited to sulfonate ester 1,2-benzoquinone-2-diazide-4-sulfonate chloride, 1,2-naphthoquinone-2-diazide-4-sulfonate chloride, 1,2-naphthoquinone-diazide-5-sulfonate chloride, 1,2-naphthoquinone-1-diazide-6-sulfonate chloride, or 1,2-benzoquinone-1-diazide-5-sulfonate chloride of quinonediazide derivatives such as 2,3,4-trihydroxybenzophenone-1,2-naphthoquinonediazide-5-sulfonate, or 2,3,4,4-tetrahydroxybenzophenone-1,2-naphthoquinonediazide-5-sulfonate, 1,2-benzoquinonediazide-4-sulfonate ester, or 1,2-naphthoquinonediazide-4-sulfonate ester. These can be used alone or in a combination of the foregoing compounds. For example y, when 2,3,4-trihydroxybenzophenone-1,2-naphthoquinonediazide-5-sulfonate, or 2,3,4,4-tetrahydroxybenzophenone-1,2-naphthoquinonediazide-5-sulfonate is used, the effect of suppressing suppresses reverse-taper and undercut phenomena of a pattern profile can be further enhanced.

The content of the quinone diazide compound may be in a range of about 0.3 to about 3 parts by weight based on the total weight of the photoresist composition. When the content of the quinone diazide compound is less than 0.3 parts by weight, a reverse tapered shape or a undercut phenomenon may not be improved. When the content of the quinone diazide compound is greater than 3 parts by weight, a residual film ratio of a portion exposed to diffracted light may be lowered or a developing speed of a non-exposed portion may be reduced, making it difficult to form a pattern.

The solvent may ensure flatness and prevent generation of coating stains, thereby allowing a uniform pattern profile to be formed.

Examples of the organic solvent may include but are not limited to alcohols such as methanol and ethanol, ethers such as tetrahydrofurane, glycol ethers such as ethylene glycol monomethyl ether and ethylene glycol monoethyl ether, ethylene glycol alkyl ether acetates such as methyl cellosolve acetate and ethyl cellosolve acetate, diethylene glycols such as diethylene glycol monomethyl ether, diethylene glycol monoethyl ether, and diethylene glycol dimethyl ether, propylene glycol monoalkyl ethers such as propylene glycol methyl ether, propylene glycol ethyl ether, propylene glycol propyl ether, and propylene glycol butyl ether, propylene glycol alkyl ether acetates such as propylene glycol methyl ether acetate, propylene glycol ethyl ether acetate, propylene glycol propyl ether acetate, and propylene glycol butyl ether acetate, propylene glycol alkyl ether propionates such as propylene glycol methyl ether propionate, propylene glycol ethyl ether propionate, propylene glycol propyl ether propionate, and propylene glycol butyl ether propionate, aromatic compounds such as toluene and xylene, ketones such as methyl ethyl ketone, cyclohexanone, and 4-hydroxy-4-methyl-2-pentanone, and ester compounds such as methyl acetate, ethyl acetate, propyl acetate, butyl acetate, ethyl 2-hydroxypropionate, methyl 2-hydroxy-2-methyl propionate, ethyl 2-hydroxy-2-methyl propionate, methyl hydroxyacetate, ethyl hydroxyacetate, butyl hydroxyacetate, methyl lactate, ethyl lactate, propyl lactate sulfate, butyl lactate, methyl 3-hydroxypropionate, ethyl 3-hydroxypropionate, propyl 3-hydroxypropionate, butyl 3-hydroxypropionate, methyl 2-hydroxy-3-methyl butanoate, methyl methoxyacetate, ethyl methoxyacetate, propyl methoxyacetate, butyl methoxyacetate, methyl ethoxyacetate, ethyl ethoxyacetate, propyl ethoxyacetate, butyl ethoxyacetate, methyl propoxyacetate, ethyl propoxyacetate, propyl propoxyacetate, butyl propoxyacetate, methyl butoxyacetate, ethyl butoxyacetate, propyl butoxyacetate, butyl butoxyacetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate. These can be used alone or in a combination thereof. When at least one selected from the group consisting of glycol ethers, ethylene glycol alkyl ether acetates and diethylene glycols, the solvent exhibits good solubility and reactivity and easily forms a coating layer.

The photoresist composition according to an exemplary embodiment of the present invention may optionally further include an additive such as, for example, a photosensitizer, an adhesion promotion agent, a surfactant, etc.

The surfactant may improve coating characteristics and developing performance of the photoresist composition. Examples of the surfactant may include but are not limited to polyoxyethylene octylphenylether, polyoxyethylene nonylphenylether, F171, F172, F173 (trade name, manufactured by Dainippon Ink in Japan), FC430, FC431 (trade name, manufactured by Sumitomo 3M in Japan), KP341 (trade name, manufactured by Shin-Etsu Chemical in Japan), etc. These can be used alone or in a combination thereof. The content of the surfactant may be in a range of about 0.0001 to about 2 parts by weight based on the total content of the photoresist composition. The adhesion promotion agent contained in the range of about 0.0001 to about 2 parts by weight can improve coating and developing performance.

The adhesion promotion agent can improve adhesion between the substrate and a photoresist pattern formed from the photoresist composition. Examples of the adhesion promotion agents can include but are not limited to a silane coupling agent containing a reactive substitution group such as a carboxyl group, a methacrylic group, an isocyanate group, or an epoxy group. Specifically, examples of the silane coupling agent can include but are not limited to γ-methacryloxypropyl trimethoxy silane, vinyl triacetoxy silane, vinyl trimethoxy silane, γ-isocyanate propyl triethoxy silane, γ-glycidoxy propyl trimethoxy silane, β-(3,4-epoxy cyclohexyl)ethyl trimethoxy silane, or the like, or a combination of at least one of the foregoing silane compounds.

Hereinafter, a method of forming a photoresist pattern, according to exemplary embodiments of the invention, will be described more fully with reference to the accompanying drawings.

Method of Forming a Photoresist Pattern

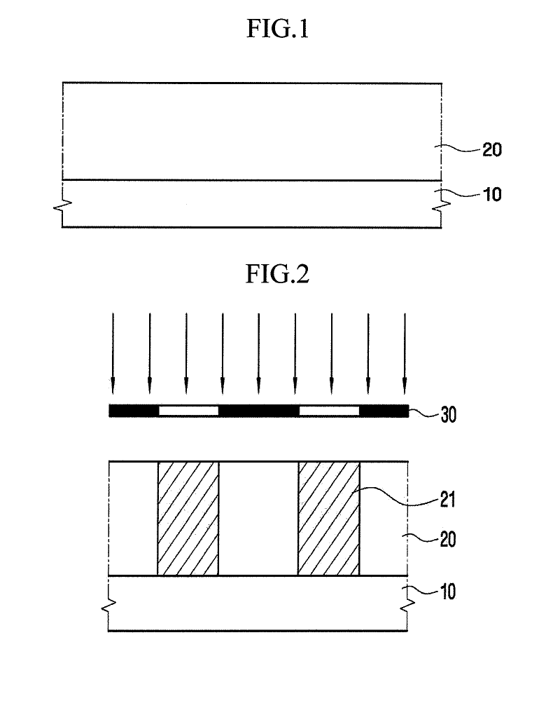

FIGS. 1 through 3 are cross-sectional views illustrating a method of forming a photoresist pattern according to an exemplary embodiment.

Referring to FIG. 1, a target product to be processed is first provided. The target product may be a substrate such as, for example, a silicon wafer or a glass substrate including a structure or a film. For example, the target product may be a substrate having a silicon nitride film. In the following, the present exemplary embodiment will be described with respect to a substrate 10 used as a target product. In this case, a cleaning process can be selectively performed on substrate 10 to remove moisture and/or any contaminants on the substrate 10.

Next, a photoresist film 20 is formed on substrate 10 by coating a photoresist composition including about 10 to about 45 parts by weight of an alkali-soluble binder resin including a hydroxyl group, about 0.1 to about 5 parts by weight of a photo-acid generator, about 1 to about 5 parts by weight of a cross-linker that cross-links the alkali-soluble binder resin, about 0.3 to about 3 parts by weight of a quinone diazide compound, and a remainder of a solvent. The photoresist film 20 can be formed using, for example, a spraying method, a roll coater method, a spin-coating method, and the like, or a combination of at least one of the foregoing methods. In an embodiment, the photoresist composition can be substantially the same as the previously described photoresist composition, and a detailed description thereof will be omitted.

After foaming the photoresist film 20, a first baking process can be performed by heating the substrate 10 with the photoresist film 20 disposed thereon. The first baking process can be performed at a temperature of, for example, about 70° C. to about 130° C. The first baking process can enhance adhesive characteristics between the photoresist film 20 and the substrate 10.

Referring to FIG. 2, the substrate 10 is exposed to light. Specifically, a mask 30, on which a selected pattern can be formed, is positioned on a mask stage of an exposure apparatus. The mask 30 can be aligned over the substrate 10, wherein the photoresist film 20 is disposed on the substrate 10.

An illumination light is irradiated onto the mask 30 for a selected time so that a portion of the photoresist film 20 is selectively reacted with light through the mask 30. Examples of the light can include but are not limited to that produced by a mercury-xenon (Hg—Xe) lamp; light of the type G-line ray or I-line ray; a krypton fluoride laser, or an argon fluoride laser; an electron beam, or X-ray, and the like.

After the exposing process, a second baking process can be additionally performed on the substrate 10. The second baking process can be performed at a temperature of, for example, about 70° C. to about 160° C. In the exposing process and the second baking process, the solubility of the exposed portion 21 of the photoresist film 20 may have solubility different from that of an unexposed portion of the photoresist film 20.

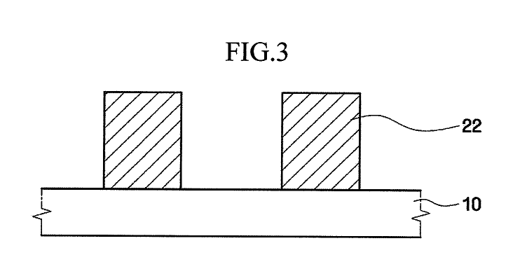

Referring to FIG. 3, the unexposed portion of the photoresist film 20 is removed using a developing solution to form a photoresist pattern 22 on the substrate 10. For example, the unexposed portion of the photoresist film 20 can be removed using a developing solution. Since the photoresist composition is a negative-type photoresist composition, the photoresist composition of the non-exposed portion is removed. A conventional developing solution such as, for example, a potassium hydroxide solution, and the like may be used as the developing solution.

Then, a cleaning process, a drying process, and other ordinary processes are performed to complete the photoresist pattern 22. Various structures of a device, such as, for example, a semiconductor device or a display device can be formed using the photoresist pattern 22 as a mask.

Hereinafter, a method of manufacturing a display device according to an exemplary embodiment will be described in detail with reference to the accompanying drawings.

Method of Manufacturing Display Device

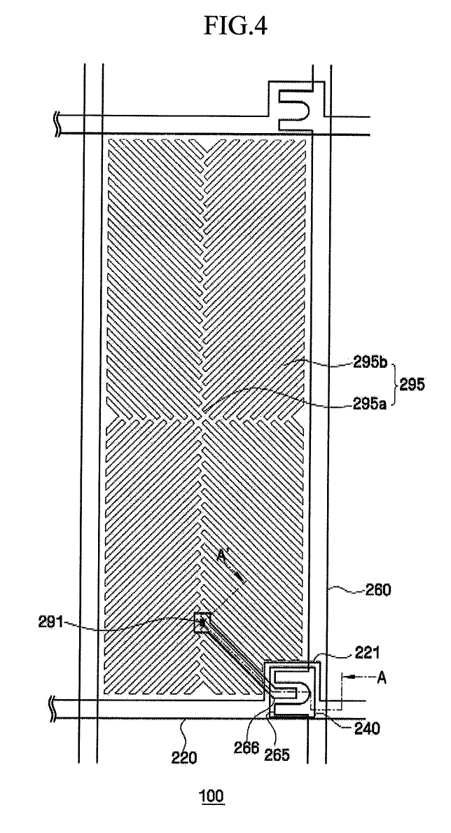

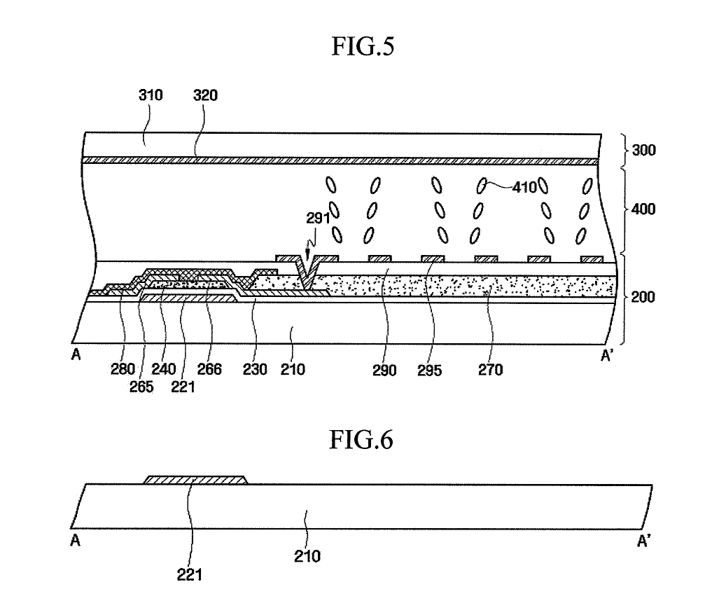

First, a display device manufactured by a manufacturing method according to an exemplary embodiment of the present invention will be described with reference to FIGS. 4 and 5. FIG. 4 is a layout view illustrating a display device manufactured by a manufacturing method according to an exemplary embodiment of the present invention, and FIG. 5 is a cross-sectional view of the display device of FIG. 4, taken along line A-A′.

A display device 100 includes a lower substrate 200 and an upper substrate 300 disposed to be opposite to and facing each other, and a liquid crystal layer 400 interposed between the two substrates 200 and 300.

A plurality of gate lines 220 may extend in one direction on a first substrate 210 made of transparent glass, or the like. One of the plurality of gate lines 220 is allocated to one pixel. A gate electrode 221 protrudes on the gate line 220. The gate lines 220 and the gate electrode 221 are collectively called gate wiring (220, 221).

Although not shown in FIG. 4, a storage line is disposed to be substantially parallel with the gate line 220 across a pixel portion. The storage line overlaps a pixel electrode 295 and forms a storage capacitor that improves charge storage capacity of a pixel.

The gate wiring (220, 221) may be made of, for example, an Al-containing metal such as aluminum (Al) or an Al alloy, a silver (Ag)-containing metal such as Ag or a Ag alloy, a copper (Cu)-containing metal such as Cu or a Cu alloy, a molybdenum (Mo)-containing metal such as Mo or a Mo alloy, chromium (Cr), titanium (Ti), or tantalum (Ta). In addition, the gate wiring (220, 221) may also have, for example, a multi-layered structure including two conductive films (not shown) having different physical characteristics. One of the two films may be made of a low resistivity metal such as, for example, an Al-containing metal, an Ag-containing metal, or a Cu-containing metal for reducing signal delay or voltage drop. The other film may be made of a material such as, for example, a Mo-containing metal, Cr, Ti, or Ta, which has good contact characteristics with other materials such as indium tin oxide (ITO) or indium zinc oxide (IZO). Examples of the combination of the two films are a lower Cr film/an upper Al film and a lower Al film/an upper Mo film. However, the gate wiring (220, 221) is not limited to those listed above and may be made of various metals or conductors.

A gate insulating layer 230 made of, for example, silicon nitride (SiNx) or silicon oxide (SiOx) is formed on the gate wiring (220, 221).

A semiconductor layer 240 preferably made of, for example, hydrogenated amorphous silicon (abbreviated to “a-Si”) or polysilicon is formed on the gate insulating layer 230. The semiconductor layer 240 may have various shapes such as, for example, an island shape, or a stripe shape. For example, as shown in FIG. 4, the semiconductor layer 240 may be formed on the gate electrode 221 in an island shape. In an alternative embodiment of the present invention in which the semiconductor layer 240 is formed in a stripe shape, the semiconductor layer 240 may be formed under a data line 260 to have a shape extending to an upper portion of the gate electrode 221.

The data line 260, a source electrode 265 and a drain electrode 266 are formed on the semiconductor layer 240 and the gate insulating layer 230. The data line 260 extends in a column direction and intersects the gate line 220 to define a pixel. The source electrode 265 extends from the data line 260 in the form of a branch to an upper portion of the semiconductor layer 240. The drain electrode 266 is positioned on the semiconductor layer 240 to be separated from the source electrode 265 and face the source electrode 265 in view of the gate electrode 221. The drain electrode 266 includes a stripe pattern disposed on the semiconductor layer 240, and a pad pattern extending from the stripe pattern and having a wider area than the stripe pattern. A contact hole 291 is positioned on the pad pattern.

The data line 260, the source electrode 265 and the drain electrode 266 are collectively called data wiring (260, 265, 266).

The data wiring (260, 265, 266) may be made of a refractory metal such as, for example, Cr, a Mo-containing metal, Ta, or Ti. The data wiring (260, 265, 266) may have, for example, a multilayered structure including a refractory metal lower film (not shown) and a low resistivity upper film (not shown). Examples of the multi-layered structure may include but are not limited to a double-layered structure including a lower Cr film/an upper Al film or a lower Al film/an upper Mo film, and a triple-layered structure of a lower Mo film, an intermediate Al film, and an upper Mo film.

At least a portion of the source electrode 265 overlaps the semiconductor layer 240. The drain electrode 266 faces the source electrode 265 in view of the gate electrode 221 and at least a portion thereof overlaps the semiconductor layer 240.

Color filters 270 are formed on the data line 260, the drain electrode 266 and the exposed semiconductor layer 240. The color filters 270 may be made of a photosensitive organic material such as, for example, a photoresist. The color filters 270 may be any one of red, green and blue filters formed at each pixel. Colors of the color filters 270 formed at the respective pixels may be arranged in various manners. The color filters 270 may be formed to have the same thickness or to have a constant step difference.

A black matrix 280 may be formed at the exterior side of the color filter 270. The black matrix 280 may serve to shield light and suppresses light leakage from regions other than pixel regions. The black matrix 280 may be formed on a thin film transistor (TFT) having the gate electrode 221, the source electrode 265 and the drain electrode 266 as three terminals. For example, the black matrix 280 may be made of an opaque material such as Cr and prevent light leakage to improve picture quality. To maximize an aperture ratio, the black matrix 280 may be formed to overlap the gate wiring (220, 221) and/or the data wiring (260, 265, 266).

A passivation layer 290 is formed on the black matrix 280 and the color filter 270. For example, the passivation layer 290 may be made of an inorganic material made of silicon nitride (SiNx) or silicon oxide (SiOx), an organic material having good flatness characteristics and photosensitivity, or an insulating material having a low dielectric constant such as a-Si:C:O or a-Si:O:F, formed using plasma enhanced chemical vapor deposition (PECVD). In addition, the passivation layer 290 may have, for example, a double-layered structure including an inorganic lower layer and an organic upper layer to protect an exposed portion of the semiconductor layer 240 while maintaining good characteristics as an organic layer.

A contact hole 291 exposing the drain electrode 266 is formed in the passivation layer 290 and the color filter 270.

A pixel electrode 295 electrically connected to the drain electrode 266 for each pixel through the contact hole 291 is formed on the passivation layer 290. That is to say, the pixel electrode 295 is physically and electrically connected to the drain electrode 266 through the contact hole 291 to then receive a data voltage from the drain electrode 266. The pixel electrode 295 is made of a transparent conductor made of, for example, indium tin oxide (ITO) or indium zinc oxide (IZO).

The pixel electrode 295 includes a connection electrode 295a and a fine pattern 295b. For example, the pixel electrode 295 includes the connection electrode 295a formed at the center of a pixel, and the fine pattern 295b branched from the connection electrode 295a in four directions. The fine pattern 295b is formed by patterning a transparent conductor such as, for example, ITO or IZO and is integrally formed with the connection electrode 295a.

The fine pattern 295b may be branched in four different directions to form domains. There may be a different of 90° in the direction in which the fine pattern 295b is branched. Here, the sum of a width of the fine pattern 295b and a width of a pitch between two adjacent fine patterns 295b may be less than or equal to 6 μm.

A display device 100 manufactured by the manufacturing method according to an embodiment of the present invention includes a pixel electrode 295, a color filter 270 and a black matrix 280 provided on a lower substrate 200. The illustrated display device 100 has a black matrix on array (BOA) structure in which the black matrix 280 is formed on a thin film transistor array. However, the aforementioned structure has provided only for an illustrative purpose and the illustrated display device 100 may have a color filter on array (“COA”) structure, in which the color filter 270 is disposed on the TFT array, or an array on color filter (“AOC”) structure, in which a TFT array is disposed on the color filter 270.

The upper substrate 300 includes a common electrode 320 as a transparent electrode made of glass formed on a second substrate 310. The common electrode 320 that is not patterned is integrally formed on a pixel area. The common electrode 320 and the pixel electrode 295 form an electrical field to rotate liquid crystal molecules.

Hereinafter, the manufacturing method of the display device according to an embodiment of the present invention will be described in detail with reference to FIGS. 4 through 15. FIGS. 6 through 15 are cross-sectional views illustrating a method for manufacturing the display device shown in FIG. 4.

First, as shown in FIG. 6, a gate line (220 of FIG. 4) and a gate electrode 221 are formed on the first substrate 210.

The first substrate 210 may be made of, for example, glass such as soda lime glass or borosilicate glass, or plastic. A sputtering method may be used in forming the gate electrode 221. Wet etching or dry etching may be used in patterning the gate electrode 221. In a case of wet etching, an etchant such as, for example, phosphoric acid, nitric acid, or acetic acid may be used. In a case of dry etching, a chlorine-based etching gas such as, for example, chlorine (Cl₂), boron trichloride (BCl₃), or the like.

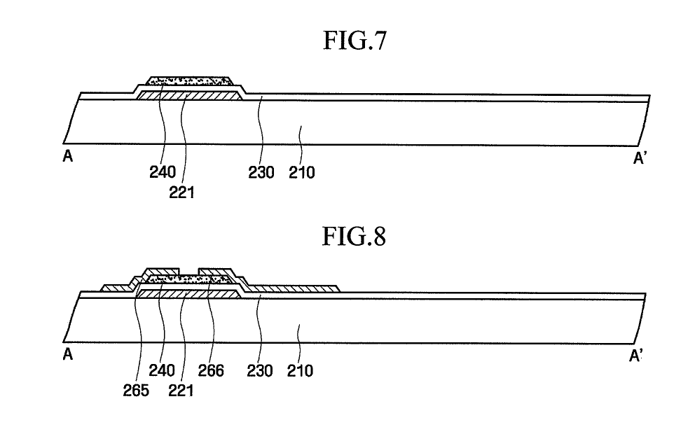

Referring to FIG. 7, gate insulating layer 230 made of fluorine-based silicon is formed on the first substrate 210 and the gate electrode 221 using plasma enhanced chemical vapor deposition (PECVD) or reactive sputtering. Subsequently, a semiconductor layer 240 is formed on the gate insulating layer 230. Here, the semiconductor layer 240 may be made of, for example, an oxide semiconductor.

Next, referring to FIG. 8, data wiring (260, 265, and 266 of FIG. 4) is formed on the gate insulating layer 230 and the semiconductor layer 240 using, for example, sputtering. The source electrode 265 and the drain electrode 266 are separated from each other in opposite directions in view of the gate electrode 221, and the drain electrode 266 extends to the pixel area.

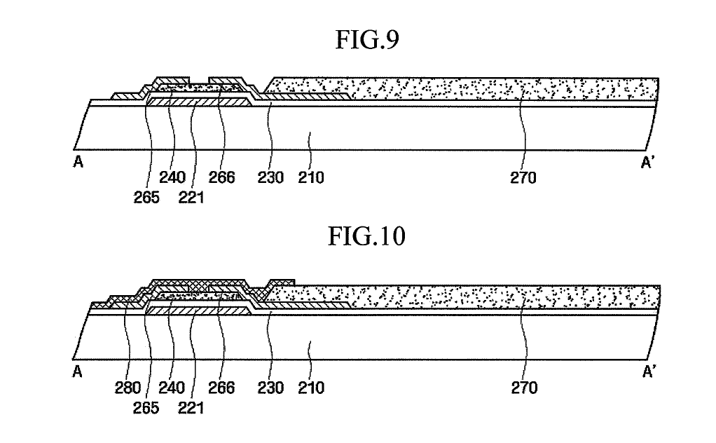

Referring to FIG. 9, the color filter 270 is formed in the pixel area on the drain electrode 266 and the gate insulating layer 230. When the color filter 270 is made of a photosensitive organic material such as, for example, a photoresist, a mask for each of red, green and blue colors may be required.

Referring to FIG. 10, the black matrix 280 is formed to overlap an upper portion of a TFT having a gate electrode 221, a source electrode 265 and a drain electrode 266 as three terminals, the gate wiring (220 and 221 of FIG. 4) and the data wiring (260, 265, and 266 of FIG. 4). The black matrix 280 is made of an opaque material to prevent light leakage, and may be formed in all areas except for the pixel area through which light is transmitted.

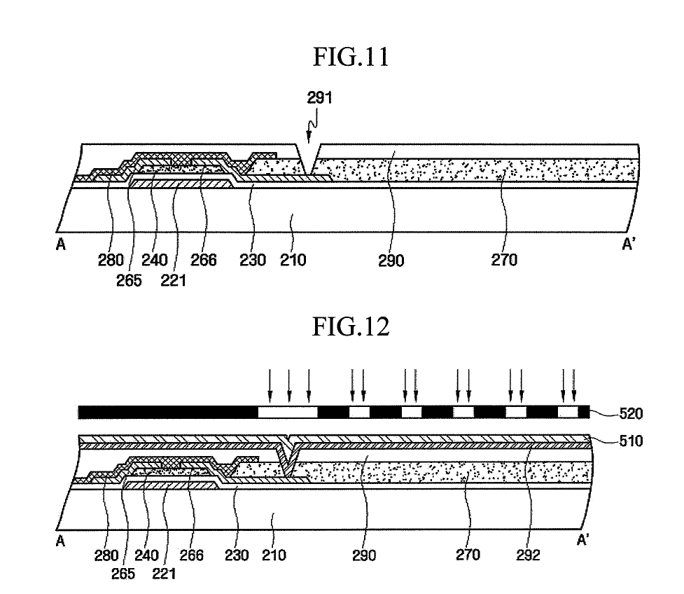

Referring to FIG. 11, a passivation layer 290 made of, for example, chlorine-based silicon is formed on the resultant product shown in FIG. 10 using PECVD or reactive sputtering. Next, the color filter 270 and the passivation layer 290 are patterned using photolithography to form a contact hole 291 exposing the drain electrode 266.

Next, referring to FIG. 12, a conductive film 292 for forming a pixel electrode is formed on the passivation layer 290. Next, a photoresist composition is coated on the conductive film 292 for forming a pixel electrode, thereby forming a photoresist film 510. The photoresist composition including about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent. The photoresist film 510 may be coated using, for example, a spraying method, a roll coater method, a spin-coating method.

Methods of forming the photoresist composition and the photoresist pattern are substantially the same as those of the previously described methods, and a detailed description thereof will be omitted.

The first substrate 210 having the photoresist film 510 is exposed to light. For example, a mask 520 having a predetermined pattern is placed on a mask stage of an exposure apparatus, and light is irradiated for a predetermined time.

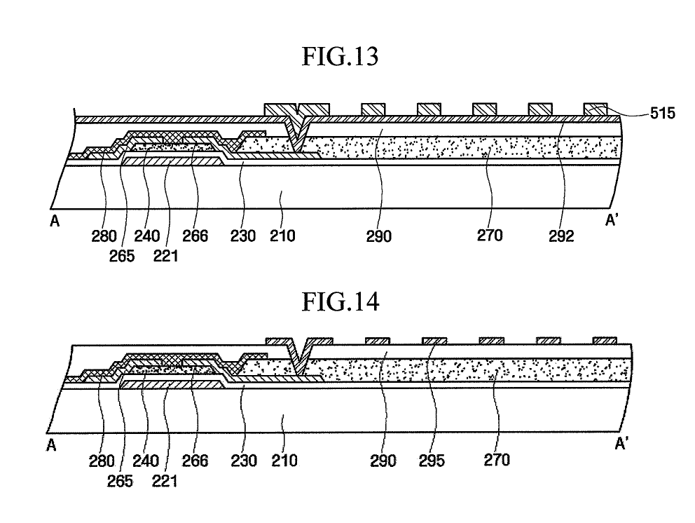

Referring to FIGS. 12 and 13, a portion of the photoresist film 510, which is not irradiated, is removed using a developing solution, thereby forming a photoresist pattern 515.

Next, referring to FIGS. 13 and 14, the conductive film 292 for forming a pixel electrode is etched using the formed photoresist pattern 515 as an etch mask, thereby forming the pixel electrode 295.

A high resolution pattern having the overall pitch of 6 μm or less between the fine patterns (295b of FIG. 4) of the pixel electrode 295 can be formed using the photoresist pattern 515 formed of the photoresist composition according to the embodiment of the present invention.

In the manufacturing method of the display device according to the illustrated embodiment, the pixel electrode is formed using the photoresist pattern formed of the photoresist composition. However, the invention is not limited to the above-described manufacturing method, and another electrode pattern or semiconductor layer pattern may also be formed using the photoresist pattern formed of the photoresist composition according to the embodiment of the present invention.

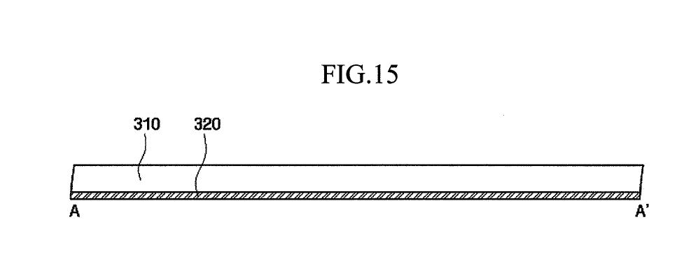

Referring to FIG. 15, a common electrode 320 is formed on the second substrate 310.

Finally, referring FIG. 5, the structure shown in FIG. 14 and the structure shown in FIG. 15 are arranged opposite to each other, and the liquid crystal layer 400 is interposed therebetween.

The methods of forming the photoresist composition and the photoresist pattern according to the embodiment of the present invention will now be described with reference to specific examples and experimental examples.

### Example 1

A photoresist composition was prepared by mixing 22 parts by weight of a novolac resin as an alkali-soluble binder resin including a hydroxyl group, having a polystyrene-reduced weight average molecular weight of 5000, 3 parts by weight of nitrobenzyl sulfonate ester as a photo-acid generator, 5 parts by weight of hexamethoxy methylmelamine as a cross-linker, 0.5 parts by weight of 2,3,4-trihydroxybenzophenone-1,2-naphthoquinonediazide-5-sulfonate as a quinone diazide compound, and 69.5 parts by weight of propylene glycol methyl ether acetate as a solvent.

### Example 2

A photoresist composition was prepared by substantially the same method as Example 1, except that 2.0 parts by weight of 2,3,4-trihydroxybenzophenone-1,2-naphthoquinonediazide-5-sulfonate was used as a quinone diazide compound, and 68.0 parts by weight of propylene glycol methyl ether acetate was used as a solvent.

### Comparative Example 1

A photoresist composition was prepared by substantially the same method as Example 1, except that a quinone diazide compound was not used and 70.0 parts by weight of propylene glycol methyl ether acetate was used as a solvent.

### Comparative Example 2

A photoresist composition was prepared by substantially the same method as Example 1, except that 0.2 parts by weight of 2,3,4-trihydroxybenzophenone-1,2-naphthoquinonediazide-5-sulfonate was used as a quinone diazide compound, and 69.8 parts by weight of propylene glycol methyl ether acetate was used as a solvent.

### Comparative Example 3

A photoresist composition was prepared by substantially the same method as Example 1, except that 4.0 parts by weight of 2,3,4-trihydroxybenzophenone-1,2-naphthoquinonediazide-5-sulfonate was used as a quinone diazide compound, and 66.0 parts by weight of propylene glycol methyl ether acetate was used as a solvent.

### Comparative Example 4

A photoresist composition was prepared by substantially the same method as Example 1, except that 5.0 parts by weight of 2,3,4-trihydroxybenzophenone-1,2-naphthoquinonediazide-5-sulfonate was used as a quinone diazide compound, and 65.0 parts by weight of propylene glycol methyl ether acetate was used as a solvent.

Evaluation of Photoresist Patterns

Photoresist patterns were formed using the photoresist compositions prepared in Examples 1 and 2 and Comparative Examples 1 through 4. Specifically, the photoresist compositions prepared in Examples 1 and 2 and Comparative Examples 1 through 4 are coated on a glass substrate using a spin coater, and baked on a hot plate at 110° C. for 90 seconds. A mask having a predetermined pattern is placed on the formed film, and an exposure process is performed with sensitivity in a range of 10-100 mJ, followed by baking for 90 seconds on a hot plate. Thereafter, a developing process is performed using an aqueous solution of 2.38 parts by weight of tetramethyl ammonium hydroxide for 70 seconds, and cleaned for one minute using ultrapure water. Then, the developed pattern was baked on a hot plate at 130° C. for 150 seconds, thereby forming a photoresist pattern.

A tapered angle of each of the photoresist patterns formed of the photoresist compositions prepared in Examples 1 and 2 and Comparative Examples 1 through 4 was measured, developing performance depending on the thickness were evaluated, and presence of undercut phenomena of the underlying photoresist films was observed. The evaluation results are listed in Table 1. If a taper angle of a photoresist pattern is greater than 90°, a reverse taper phenomenon occurs. In this case, size analysis errors of the photoresist patterns may be caused after the developing process, lowering processing efficiency. In view of processing efficiency, maintaining a taper angle at 90° or less is desirable. To evaluate the developing performance depending on the thickness through the developing process performed using an aqueous solution of 2.38 parts by weight of tetramethyl ammonium hydroxide for 70 seconds, the developing performance was determined to be “bad” when the developing process was not properly performed with the thickness in a range of 3 μm to 5 μm, “good” when the developing process was performed with the thickness in a range of 3 μm to 5 μm, and “superior” when the developing process was performed with the thickness beyond the range stated above.

TABLE 1

| | | | Presence or Absence |
|---|---|---|---|
| | Taper | Developing Performance | of Undercut |
| | Angle | depending on Thickness | Pattern Profile |
| Example 1 | 89° | Superior | Absent |
| Example 2 | 83° | Good | Absent |
| Comparative | 100° | Superior | Present |
| Example 1 | | | |
| Comparative | 92° | Superior | Present |
| Example 2 | | | |
| Comparative | 70° | Poor | Absent |
| Example 3 | | | |
| Comparative | 52° | Poor | Absent |
| Example 4 | | | |

As understood from the results shown in Table 1, the photoresist patterns formed of the photoresist compositions prepared in Examples 1 and 2 demonstrated excellent characteristics, that is, no reverse-tapered shapes occurred, good or superior developing performance, and no undercut phenomenon occurred. By contrast, the photoresist patterns formed of the photoresist compositions prepared in Comparative Examples 1 through 4 demonstrated poor characteristics, that is, reverse-tapered shapes occurred, poor developing performance, and undercut phenomena occurred.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A photoresist composition comprising:
about 10 to about 45 parts by weight of an alkali soluble binder resin including a hydroxyl group;
about 0.1 to about 5 parts by weight of a photo-acid generator;
about 1 to about 5 parts by weight of a cross-linker that cross-links the alkali-soluble binder resin including the hydroxyl group;
about 0.3 to about 3 parts by weight of a quinone diazide compound; and
a remainder of a solvent.

2. The photoresist composition of claim 1, wherein the alkali-soluble binder resin including the hydroxyl group is a novolac resin having a polystyrene-reduced weight average molecular weight in a range from about 1,000 to about 10,000.

3. The photoresist composition of claim 2, wherein the novolac resin is obtained by condensation of m-cresol and p-cresol as phenolic compounds mixed in a ratio of about 30:70 to about 70:30 by weight.

4. The photoresist composition of claim 1, wherein the photo-acid generator includes at least one selected from the group consisting of an aromatic sulfonic acid ester, an aromatic iodonium salt, an aromatic sulfonium salt, and an aromatic compound containing a halogenated alkyl remainder.

5. The photoresist composition of claim 1, wherein the cross-linker includes at least one selected from the group consisting of urea-formaldehyde, melamine-formaldehyde, benzoguanamine-formaldehyde, glycoluril-formaldehyde, and hexa(methoxymethyl)melamine.

6. The photoresist composition of claim 1, wherein the quinone diazide compound comprises at least one selected from the group consisting of 2,3,4-trihydroxybenzophenone-1,2-naphthoquinonediazide-5-sulfonate and 2,3,4,4-tetrahydroxybenzophenone-1,2-naphthoquinonediazide-5-sulfonate.

7. The photoresist composition of claim 1, wherein the solvent comprises at least one selected from the group consisting of glycol ethers, glycol ethers, and diethylene glycols.

8. The photoresist composition of claim 1, further comprising at least one selected from the group consisting of a photosensitizer, a surfactant, and an adhesion promotion agent.

9. The photoresist composition of claim 1, wherein the photoresist composition is a negative-type photoresist composition.

10. A method of forming a photoresist pattern comprising:
forming a photoresist film by coating a photoresist composition comprising about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent;
exposing the photoresist film to light; and
partially removing the photoresist film to form a photoresist pattern.

11. The method of claim 10, wherein the partially removing of the photoresist film comprises removing a non-exposed portion of the photoresist film.

12. The method of claim 10, wherein the alkali-soluble binder resin including a hydroxyl group is a novolac resin having a polystyrene-reduced weight average molecular weight in a range from about 1,000 to about 10,000.

13. The method of claim 12, wherein the novolac resin is obtained by condensation of m-cresol and p-cresol as phenolic compounds mixed in a ratio of about 30:70 to about 70:30 by weight.

14. The method of claim 10, wherein the photo-acid generator includes at least one selected from the group consisting of an aromatic sulfonic acid ester, an aromatic iodonium salt, an aromatic sulfonium salt, and an aromatic compound containing a halogenated alkyl remainder.

15. The method of claim 10, wherein the cross-linker includes at least one selected from the group consisting of urea-formaldehyde, melamine-formaldehyde, benzoguanamine-formaldehyde, glycoluril-formaldehyde, and hexa(methoxymethyl)melamine.

16. The method of claim 10, wherein the quinone diazide compound comprises at least one selected from the group consisting of 2,3,4-trihydroxybenzophenone-1,2-naphthoquinonediazide-5-sulfonate and 2,3,4,4-tetrahydroxybenzophenone-1,2-naphthoquinonediazide-5-sulfonate.

17. The method of claim 10, wherein the solvent comprises at least one selected from the group consisting of glycol ethers, glycol ethers, and diethylene glycols.

18. The method of claim 10, further comprising at least one selected from the group consisting of a photosensitizer, a surfactant, and an adhesion promotion agent.

19. The photoresist composition of claim 8, wherein the photoresist composition includes an adhesion promotion agent in a range of about 0.0001 to about 2 parts by weight.

20. A method for manufacturing a display device, comprising:
forming a gate line and a gate electrode on a first substrate;
forming a gate insulating layer on the first substrate and the gate electrode;
forming a semiconductor layer on the gate insulating layer;
forming a data line, a source electrode, and a drain electrode on the gate insulating layer and the semiconductor layer;
forming a color filter in a pixel area on the drain electrode and the gate insulating layer;
forming a black matrix made of opaque material overlapping an upper portion of a thin film transistor (TFT) having the gate electrode, the source electrode and the drain electrode as three terminals;
forming a passivation layer on the color filter and the black matrix;
forming a conductive film for forming a pixel electrode on the passivation layer;
forming a photoresist film by coating a photoresist composition comprising about 10 to about 45 parts by weight of an alkali soluble binder resin including a hydroxyl group, about 0.1 to about 5 parts by weight of a photo-acid generator, about 1 to about 5 parts by weight of a cross-linker that cross-links the alkali-soluble binder resin including the hydroxyl group, about 0.3 to about 3 parts by weight of a quinone diazide compound, and a remainder of a solvent;
exposing the photoresist film to light;
partially removing a portion of the photoresist film which is not exposed to light using a development solution to thereby form a photoresist pattern;
etching the conductive film for forming the pixel electrode using the formed photoresist pattern as an etch mask, thereby forming the pixel electrode; and
forming a second substrate including a common electrode on the pixel area of the first substrate.
